(19) United States
(12) Patent Application Publication
(10) Pub. No.: US 2008/0138960 A1
(43) Pub. Date: Jun. 12, 2008

(54) METHOD OF MANUFACTURING A STACK-TYPE SEMICONDUCTOR DEVICE

(76) Inventors: Sang-Yeob Han, Anyang-si (KR); Chang-Ki Hong, Seongnam-si (KR); Bo-Un Yoon, Seoul (KR); Young-Ho Koh, Seongnam-si (KR); Seong-Kyu Yun, Seoul (KR); Jong-Heun Lim, Seoul (KR)

Correspondence Address: F. CHAU & ASSOCIATES, LLC, 130 WOODBURY ROAD, WOODBURY, NY, 11797, US

(21) Appl. No.: 11/936,965

(22) Filed: Nov. 8, 2007

(30) Foreign Application Priority Data
Dec. 11, 2006 (KR) 2006-125701

(51) Int. Cl. H01L 21/30

(52) U.S. Cl. 438/458; 257/E21.211

(57) ABSTRACT

A method of manufacturing a stack-type semiconductor device, in which a first substrate and a second substrate are prepared so that the first substrate has a surface layer and the second substrate has an insulation layer. The first substrate and the second substrate are attached to each other to allow the surface layer to make contact with the insulation layer. The first substrate is partially separated from the second substrate to allow the surface layer to remain on a central portion of the second substrate. A sacrificial layer pattern is then formed on an edge portion of the second substrate having the surface layer. The sacrificial layer pattern and the surface layer are planarized. Thus, the sacrificial layer pattern may reduce damage to the edge portion of the second substrate so that the second substrate may have an improved flatness.

### CROSS-REFERENCE TO RELATED APPLICATION

This application claims priority under 35 USC § 119 to Korean Patent Application No. 2006-125701 filed on Dec. 11, 2006 the contents of which are herein incorporated by reference in their entirety.

### BACKGROUND OF THE INVENTION

1. Technical Field

Exemplary embodiments of the present invention relate to a method of manufacturing a stack-type semiconductor device. More specifically, exemplary embodiments of the present invention relate to a method of manufacturing a stack-type semiconductor device that includes a process for forming a silicon-on-insulator (SOI) substrate by an ion-cutting technique including implanting ions into two substrates, attaching the two substrates, and separating the two substrates.

2. Discussion of Related Art

Generally, as semiconductor devices have become more highly integrated, a leakage current in a junction region caused by a parasitic capacitance may increase the power consumption of the semiconductor device. This may block fabricating a semiconductor device requiring a rapid operation speed and a low power.

More specifically, as the channel length of a transistor which may occupy a large area of the semiconductor device, has shrunken to no more than about 0.5 μm, the integration degree of a semiconductor substrate has been increased. Therefore, the junction capacitance and leakage current in the source/drain electrodes of an MOS transistor may be increased. As a result, to provide the semiconductor device with the rapid operational speed and the low power by reducing the parasitic capacitance and the leakage current, a silicon-on-insulator (SOI) substrate has been widely used.

The SOI substrate may be manufactured by forming a silicon oxide layer as an insulation layer on a silicon substrate, forming a single crystalline silicon layer on the silicon oxide layer, and forming a semiconductor device on the single crystalline silicon layer. In this case, in a semiconductor device manufacturing process using a silicon substrate, a parasitic capacitance between a circuit and the silicon substrate may cause a slow operation speed of the semiconductor device. In the SOI substrate, however, the insulation layer may prevent the parasitic capacitance from being generated. Furthermore, adjacent devices in the SOI substrate may be readily separated. The SOI substrate may also have excellent electrical characteristics: such as a low voltage of below about 1V of an electronic circuit element, a high speed, a tow power, and the like. Thus, the SOI substrate may be widely used for a large-scale integrated (LSI) circuit, a Gb-DRAM, a radiation-resistant high circuit, a micro electro mechanical system (MEMS), a solar cell, and the like.

The SOI may be manufactured by separation through an implanted oxygen (SIMOX) method or by an ion cutting method. According to the SIMOX method, oxygen atoms are implanted into a silicon substrate to form a substrate doped with the oxygen atoms. The substrate doped with the oxygen atoms is then annealed to form the SOI substrate.

A trench is then formed at a surface portion of the SOI substrate. The trench is filled with an insulation layer to form a field region and an active region of the SOI substrate. When a fundamental electrode of the MOS transistor is formed on the SOI substrate source/drain electrodes of the MOS transistor may make contact with an insulation layer under a silicon layer in the active region so that a junction capacitance and a leakage current may not exist. As a result, the semiconductor substrate may be provided with the low power and the rapid operational speed. Additionally, the devices may be electrically isolated from each other by the insulation layer.

In contrast, according to the ion cutting method, substrates having insulation layers are attached to each other. The attached substrates are then etched-back. More specifically, hydrogen ions are implanted into a first substrate having a silicon oxide layer to form an ion implantation region in the first substrate. The first substrate is attached to a second substrate at a high temperature. The first substrate is then separated from the ion implantation region. The second substrate is thermally treated and chemically mechanically polished to form the SOI substrate having a low surface roughness. The SOI substrate manufactured by the ion cutting method may have excellent characteristics such as a uniform thickness, crystallization, and the like, compared to that manufactured by the SIMOX method. Additionally, the ion cutting method may be compatible with a general semiconductor fabrication process. Furthermore, the first substrate may be reused for manufacturing a new SOI substrate.

When the SOI substrate is manufactured by the ion cutting method, however it may be very difficult to provide the second substrate with a uniform surface layer. More specifically, an edge portion of the second substrate may have an upper face lower than that of the central portion of the second substrate. That is, a stepped portion may be formed between the edge portion and the central portion. Because the edge portion of the second substrate has a rounded shape, the rounded edge portion may not be attached to the first substrate. Thus, the edge portion of the second substrate may not be separated along a line substantially horizontal with a cut face of the separated first substrate to form the stepped portion. Moreover, as shown in FIG. 1, when the surface layer of the second substrate is planarized by a chemical mechanical polishing (CMP) process, the surface layer may be planarized from a point spaced apart from the edge portion by several millimeters so that a curved portion I may be formed at the edge portion. The curved portion I may cause a poor flatness of the substrate W.

### SUMMARY OF THE INVENTION

Exemplary embodiments of the present invention provide a method of manufacturing a stack-type semiconductor device that is capable of preventing a reduction in the surface flatness of a substrate, which is caused by a curved portion at a surface portion of the substrate generated after performing a chemical mechanical polishing (CMP) process on a silicon-on-insulator (SOI) substrate having a surface layer.

In a method of manufacturing a stack-type semiconductor device in accordance with an exemplary embodiment of the present invention, a first substrate and a second substrate are prepared. In this exemplary embodiment, the first substrate has a surface layer and the second substrate has an insulation layer. The first substrate and the second substrate are attached to each other to allow the surface layer to make contact with the insulation layer. The first substrate is partially separated from the second substrate to allow the surface layer to remain on a central portion of the second substrate. A sacrificial layer pattern is then formed on an edge portion of the second substrate having the surface layer. The sacrificial layer pattern and the surface layer are planarized.

In this exemplary embodiment, the sacrificial layer pattern may have a thickness greater than or substantially equal to the thickness of the surface layer.

According to an exemplary embodiment, forming the sacrificial layer pattern may include forming a sacrificial layer on the second substrate having the surface layer, forming a mask pattern on the sacrificial layer to expose a central portion of the sacrificial layer corresponding to the surface layer, and etching the sacrificial layer using the mask pattern as an etching mask. In this exemplary embodiment, the sacrificial layer may include single crystalline silicon, polysilicon, oxide, and the like. Additionally, the mask pattern may include a photoresist pattern.

According an exemplary example embodiment of the present invention, forming the sacrificial layer pattern may include forming a sacrificial layer on the second substrate, and removing a central portion of the sacrificial layer corresponding to the surface layer. In this exemplary embodiment, the sacrificial layer may include a photoresist film. Additionally, the central portion of the sacrificial layer may be removed by a photolithography process.

Moreover, the sacrificial layer pattern on the edge portion of the second substrate having the surface layer may have a thickness of about 2,000 Å to about 7,000 Å.

In this exemplary embodiment, the first substrate and the second substrate may include a silicon substrate.

According to an exemplary embodiment of the present invention, preparing the second substrate may include forming a gate pattern including a gate insulation layer and a gate conductive layer on the second substrate, implanting impurities into the second substrate adjacent the gate pattern using the gate pattern as an ion implantation mask to form source/drain regions, and covering the gate pattern and the source/drain regions with an oxide layer.

In this exemplary embodiment, the surface layer may have a thickness of about 200 Å to about 5,000 Å.

Additionally, before attaching the first substrate and the second substrate to each others a separation layer may be additionally formed under the surface layer of the first substrate by a hydrogen ion implantation process.

Furthermore, partially separating the first substrate may include thermally treating the attached first and second substrates at a temperature of about 300° C. to about 700° C.

Moreover, the sacrificial layer pattern and the surface layer may be planarized by a chemical mechanical polishing (CMP) process.

According to an exemplary embodiment of the present invention, the sacrificial layer pattern may be formed on the edge portion of the second substrate having the surface layer. Thus, defects such as a curved portion may not be generated at the surface of the second substrate when the second substrate having the surface layer is chemically mechanically polished. As a result, the second substrate may have an improved flatness.

### BRIEF DESCRIPTION OF THE DRAWINGS

Exemplary embodiments of the present invention will be understood in more detail from the following descriptions taken in conjunction with the accompanying drawings, wherein:

FIG. 1 is a cross-sectional view illustrating a conventional SOI substrate on which a CMP process is carried out;

FIGS. 2 to 8 are cross-sectional views illustrating a method of manufacturing a stack-type semiconductor device in accordance with an exemplary embodiment of the present invention;

FIG. 9 is a cross-sectional view illustrating a method of manufacturing a stack-type semiconductor device in accordance with an exemplary embodiment of the present invention; and

FIG. 10 is a plan view illustrating a substrate formed by a method in accordance with an exemplary embodiment of the present invention.

### DETAILED DESCRIPTION OF EXEMPLARY EMBODIMENTS

The present invention is described more fully hereinafter with reference to the accompanying drawings, in which exemplary embodiments of the present invention are shown. This invention may, however, be embodied in many different forms and should not be construed as limited to the exemplary embodiments set forth herein. Rather, these exemplary embodiments are provided so that this disclosure will be thorough and complete, and will fully convey the scope of the invention to those of ordinary skill in the art.

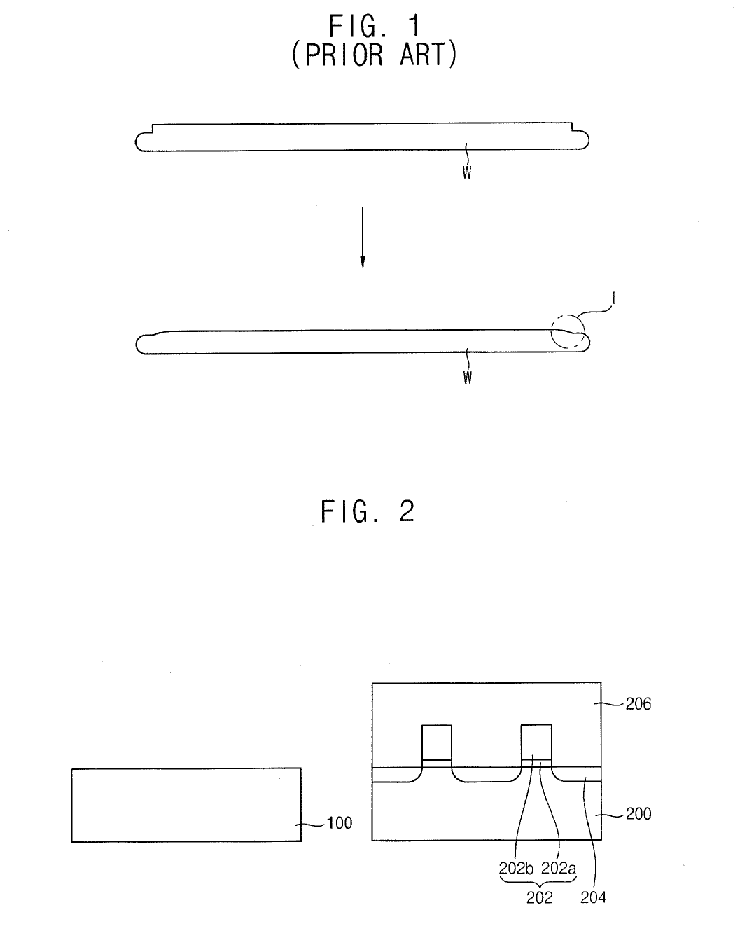

FIGS. 2 to 8 are cross-sectional views illustrating a method of manufacturing a stack-type semiconductor device in accordance with an exemplary embodiment of the present invention.

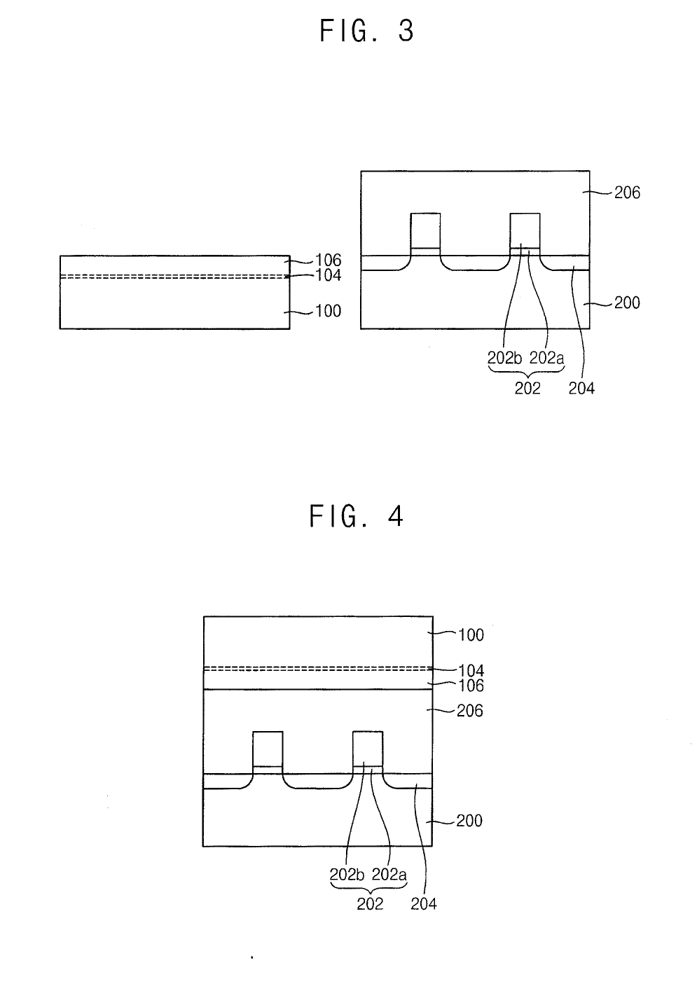

Referring to FIG. 2, a first substrate 100 and a second substrate 200 are prepared. The first substrate 100 includes a surface layer 106 (see FIG. 4) that is included in a stack-type semiconductor device. An insulation interlayer 206 is formed on the second substrate 200. In this exemplary embodiment, the first substrate 100 may be referred to as a donor substrate, and the second substrate 200 may be referred to as a handling substrate. Examples of the first substrate 100 and the second substrate 200 may include a silicon substrate, a silicon-on-insulator (SOI) substrate, a germanium substrate, a geranium-on-insulator (GOI) substrate, a silicon-geranium substrate, and the like. The surface layer 106, shown in FIG. 3, of the first substrate 100 may act as a channel layer of the stack-type semiconductor device. Thus, the first substrate 100 may include a single crystalline layer obtained by performing a selective epitaxial growth (SEG) process.

A trench isolation layer (not shown) as an isolation layer may be formed in the second substrate 200 to define an active region and a field region of the second substrate 200. The trench isolation layer may have advantages in view of an integration degree of the stack-type semiconductor device.

A gate pattern 202 is then formed on the active region of the second substrate 200. In this exemplary embodiment, the gate pattern 202 may include a gate insulation layer 202a and a gate conductive layer 202b.

More specifically, an insulation layer (not shown) and a conductive layer (not shown) are formed on the second substrate 200. A photolithography process is then carried out on the insulation layer and the conductive layer to form the gate pattern 202. More specifically, a first photoresist pattern (not shown) is formed on the conductive layer to partially expose the conductive layer. The conductive layer and the insulation layer are etched using the first photoresist pattern as an etching mask to form the gate pattern 202 including the gate insulation layer 202a and the gate conductive layer 202b on the second substrate 200. The first photoresist pattern is then removed by an ashing process and/or a stripping process.

Impurities are implanted into the second substrate 200 using the gate pattern 202 as an ion implantation mask to form source/drain regions 204 doped with the impurities at surface portions of the second substrate 200 adjacent the gate pattern 202. In this exemplary embodiment, the impurities for forming the source/drain regions 204 may include boron (B), phosphorous (P), arsenic (As), and the like. In this exemplary embodiment, when the stack-type semiconductor device may include a double stack-type SRAM, forming an NMOS transistor may be needed in the second substrate. Thus, in this case, the impurities may include phosphorous (P), arsenic (As), and the like.

Alternatively, the source/drain regions 204 may have a lightly doped drain (LDD) structure. The source/drain regions 204 having the LDD structure may be formed by forming a spacer on a sidewall of the gate pattern 202, and implanting impurities into the source/drain region 204 to form an LDD region.

In this exemplary embodiment, a transistor including the gate pattern 202 and the source/drain regions 204 may be formed on the second substrate 200. Additionally, logic devices wirings, and the like, may be further formed on the second substrate 200 in accordance with the circuit design.

The insulation interlayer 206 including oxide is then formed on the second substrate 200 on which the transistor including the gate pattern 202 and the source/drain regions 204 is formed. In this exemplary embodiment, examples of the oxide may include borophosphor silicate glass (BPSG), phosphor silicate glass (PSG), undoped silicate glass (USG), spin on glass (SOG), and the like.

Referring to FIG. 3, hydrogen ions are implanted into the first substrate 100 to form a separation region 104. The separation region 104 defines the surface layer 106 in the first substrate 100 that makes contact with the second substrate 200. In this exemplary embodiment, the surface layer 106 may have a thickness of about 200 Å to about 5,000 Å. The dose of hydrogen ions for forming the separation region 104 may be about 1×10¹⁶/cm² to about 1×10¹⁷ cm₂. Additionally the separation region 104 may have a reduced thickness. When the first substrate 100 is separated from the second substrate 200 by a subsequent process, the separation region 104 may be cut to form a cut face doped with the hydrogen ions.

Referring to FIG. 4, the first substrate 100 is attached to the second substrate 200 so as to place the surface layer 106 on the insulation interlayer 206.

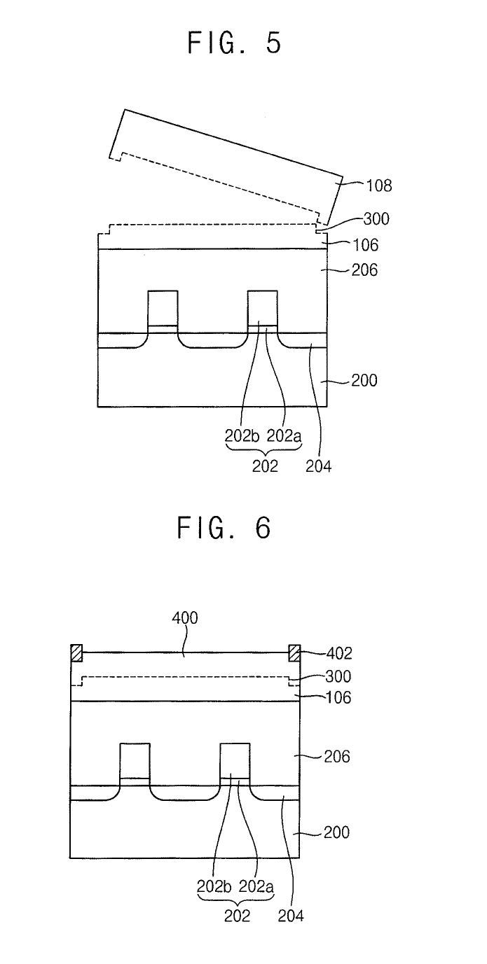

Referring to FIG. 5, the attached first and second substrates 100 and 200 are then thermally treated to cut the first substrate 100 along the separation region 104 shown in FIGS. 3 and 4. As a result, the surface layer 106 remains on a central portion of the second substrate 200 to form an SOI structure including a silicon layer, an oxide layer and a silicon layer sequentially stacked. In this exemplary embodiment, the thermal treatment may be carried out at a temperature of about 300° C. to about 700° C. When the thermal treatment is carried out at a temperature below about 300° C., the ion implantation region 104 may not be easily cut. In contrast, when the thermal treatment is carried out at a temperature of above about 700° C., a thermal budge may be applied to the semiconductor structure 205 and the oxide layer pattern 206.

In this exemplary embodiment, after the first substrate 100 is partially separated from the second substrate 200 by the thermal treatment, the bonding strength of the interface between the surface layer 106 and the second substrate 200 may be increased. Additionally, damage caused by the hydrogen ions in the first substrate 100 and the ion implantation process may be removed.

As shown in FIG. 5, a stepped portion 300 may be formed at an edge portion of the second substrate 200 having the surface layer 106. Because the edge portion of the second substrate 200 has a rounded shape, the rounded edge portion may not be attached to the first substrate 100. Thus, the edge portion of the second substrate 200 may not be cleanly separated along a line substantially horizontal with the cut face of the separated first substrate 100 to form the stepped portion 300. Here, the stepped portion 300 may have a thickness of about 3,000 Å to about 7,000 Å. The stepped portion 300 may be transformed into a curved portion during the operation in which the surface layer 106 is planarized. Thus, the stepped portion 300 may undesirably decrease the flatness of the surface layer 106. As a result, it is necessary to remove the stepped portion 300 in order to planarize the surface of the second substrate 200 and also perform additional processes for forming a wiring on the second substrate 200.

Referring to FIG. 6, a sacrificial layer 400 is formed on the second substrate 200 having the surface layer 106. A mask pattern 402 is formed on the sacrificial layer 400 to expose the central portion of the sacrificial layer 400 corresponding to the surface layer 106. In this exemplary embodiment, examples of a material that may be used for the sacrificial layer 400 may include single crystalline silicon, polysilicon, oxide, silicon oxide, and the like. Additionally, the mask pattern 402 may include a photoresist pattern.

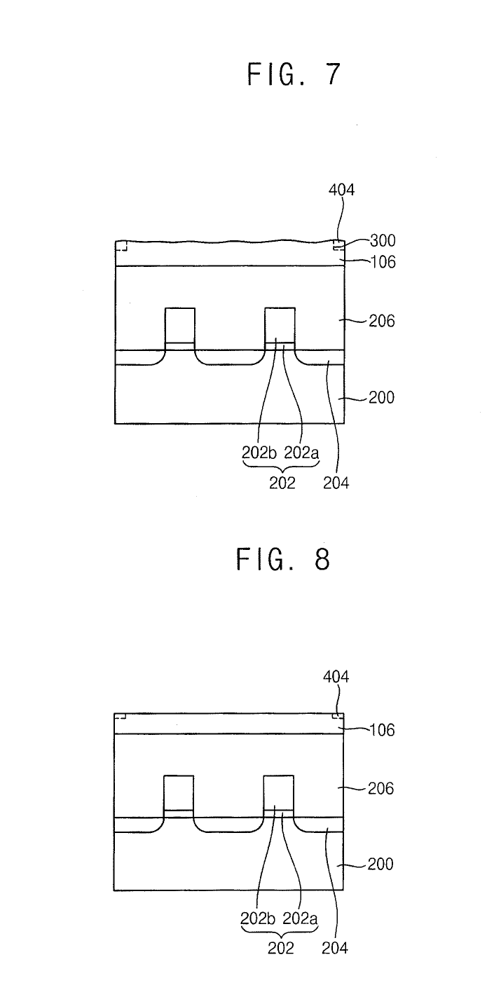

Referring to FIG. 7 the sacrificial layer 400 shown in FIG. 6: is etched using the mask pattern 402 as an etching mask until an upper face of the surface layer 106 is exposed to form a sacrificial layer pattern 404 on the edge portion of the second substrate 200 having the surface layer 106. In this exemplary embodiment, the sacrificial layer pattern 404 may have a thickness greater than or substantially equal to the thickness of the surface layer 106. Thus, the sacrificial layer pattern 404 may have a thickness of about 2,000 Å to about 7,000 Å. The mask pattern 404 is then removed by an ashing process and/or a stripping process. As a result the second substrate 200 having an SOI structure is completed. In this exemplary embodiment, the edge portion of the second substrate 200 having the SOI structure may have an upper face higher than or substantially equal to that of the central portion of the second substrate 200.

Referring to FIG. 8, the sacrificial layer pattern 404 and the surface layer 106 are planarized. In this exemplary embodiment, the sacrificial layer pattern 404 and the surface layer 106 may be planarized by a CMP process. The CMP process may use a polishing pad. The polishing pad may primarily polish the edge portion of the surface layer 106 where the sacrificial layer pattern 404 is formed. The polishing pad may secondarily polish the central portion of the surface layer 106. Thus, the polished surface layer 106 may have a flat surface.

According to this exemplary embodiment, the sacrificial layer pattern may be formed on the edge portion of the second substrate having the surface layer. Thus, the edge portion of the second substrate may have the upper face higher than that of the central portion of the second substrate. Alternatively, the edge portion of the second substrate may have the upper face on a plane substantially the same as that on which an upper face of the central portion of the second substrate is placed.

When the second substrate having the surface layer and the sacrificial layer pattern is polished, a region of the second substrate between a point spaced apart from the edge portion by several millimeters and the edge portion may be uniformly planarized, as compared to a conventional CMP process.

As a result, the stack-type semiconductor device including the SOI substrate where the channel layer having a flat surface is formed may be manufactured.

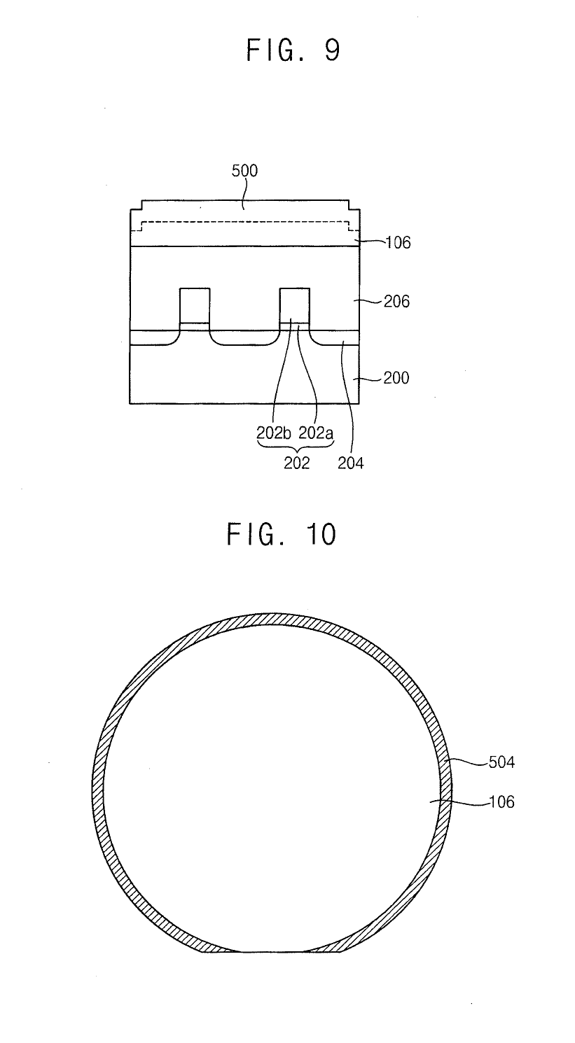

FIG. 9 is a cross-sectional view illustrating a method of manufacturing a stack-type semiconductor device in accordance with an exemplary embodiment of the present invention, and FIG. 10 is a plan view illustrating a semiconductor device formed by the method described relative to FIG. 9.

A method of manufacturing a stack-type semiconductor device in accordance with this exemplary embodiment is substantially the same as that described in relation to FIGS. 2-8 except for a process for forming a sacrificial layer pattern on an edge portion of a second substrate having a surface layer. Thus, the same reference numerals refer to the same elements and any further illustrations with respect to the same elements are omitted herein for brevity.

Initially, processes substantially the same as those illustrated with reference to FIGS. 2 to 4 are carried out to form the structure in FIG. 9,

Referring to FIG. 9, a sacrificial layer 500 is formed on the second substrate 200 having the central portion to which the surface layer 106 is attached. In this exemplary embodiment, the sacrificial layer 500 may include a photoresist pattern. The sacrificial layer 500 may be formed by a spin coating process.

Referring to FIG. 10, a central portion of the sacrificial layer 500 corresponding to the surface layer 106 is then removed by a photolithography process. In this exemplary embodiment, the sacrificial layer 500 including photoresist may be chemically reacted by an exposing process and a developing process to partially remove the sacrificial layer 500 on the central portion of the second substrate 200, thereby forming a sacrificial layer pattern 504 around the central portion of the second substrate 200.

The methods of manufacturing the stack-type semiconductor device including the SOI substrate having the flat surface are illustrated in detail in the above-described figures. As described above, the sacrificial layer on the edge portion of the second substrate having the surface layer may be patterned using the mask pattern or removed by the photolithograph process including the exposing process and the developing process to form the sacrificial layer pattern. Thus, the sacrificial layer pattern on the edge portion of the second substrate may be previously planarized during the CMP process. The entire surface of the second substrate may be uniformly polished so that the SOI substrate may have improved surface flatness.

According to exemplary embodiments of the present invention, the first substrate and the second substrate are first attached to each other. The first substrate is then separated from the second substrate so as to allow the surface layer to remain on the second substrate. The sacrificial layer pattern is then formed on the edge portion of the second substrate, and the second substrate having the sacrificial layer pattern is planarized.

Thus, because the sacrificial layer pattern may be formed on the edge portion of the second substrate having the surface layer, defects such as a curved portion may not be generated at the surface of the second substrate when the second substrate having the surface layer is chemically mechanically polished. As a result, the second substrate may have an improved flatness.

Having described exemplary embodiments of the present invention, it is noted that modifications and variations can be made by persons of ordinary skill in the art in light of the above teachings. It is therefore to be understood that changes may be made in the exemplary embodiments of the present invention disclosed, which are within the scope and the spirit of the invention outlined by the appended claims.

What is claimed is:

1. A method of manufacturing a stack-type semiconductor device comprising:
preparing a first substrate and a second substrate, the first substrate having a surface layer and the second substrate having an insulation layer;
attaching the first substrate and the second substrate to each other to cause the surface layer to make contact with the insulation layer;
partially separating the first substrate from the second substrate to allow the surface layer to remain on a central portion of the second substrate;
forming a sacrificial layer pattern on an edge portion of the second substrate having the surface layer; and
planarizing the sacrificial layer pattern and the surface layer.

2. The method of claim 1 wherein the sacrificial layer pattern has a thickness greater than or substantially equal to a thickness of the surface layer.

3. The method of claim 1, wherein forming the sacrificial layer pattern comprises:
forming a sacrificial layer on the second substrate having the surface layer;
forming a mask pattern on the sacrificial layer to expose a central portion of the sacrificial layer corresponding to the surface layer; and
etching the sacrificial layer using the mask pattern as an etching mask.

4. The method of claim 3 wherein the sacrificial layer comprises at least one selected from the group consisting of single crystalline silicon, polysilicon and oxide.

5. The method of claim 3, wherein the mask pattern comprises a photoresist pattern.

6. The method of claim 1 wherein forming the sacrificial layer pattern comprises:
forming a sacrificial layer on the second substrate having the surface layer; and
removing a central portion of the sacrificial layer corresponding to the surface layer.

7. The method of claim 6, wherein the sacrificial layer comprises a photoresist pattern.

8. The method of claim 7, wherein the central portion of the sacrificial layer is removed by a photolithography process.

9. The method of claim 1, wherein the sacrificial layer pattern on the edge portion of the second substrate having the surface layer has a thickness of about 2,000 Å to about 7,000 Å.

10. The method of claim 1, wherein the first substrate and the second substrate comprise a silicon substrate.

11. The method of claim 1, wherein preparing the second substrate having the insulation layer comprises:
forming a gate pattern including a gate insulation layer and a gate conductive layer on the second substrate;
implanting impurities into the second substrate using the gate pattern as an ion implantation mask to form source/drain regions adjacent the gate pattern; and
covering the gate pattern and the source/drain regions with an oxide layer.

12. The method of claim 1, wherein the surface layer has a thickness of about 2,000 Å to about 5,000 Å.

13. The method of claim 1, further comprising implanting hydrogen ions into the first substrate under the surface layer to form a separation layer, before attaching the first substrate and the second substrate to each other.

14. The method of claim 1, wherein partially separating the first substrate from the second substrate comprises thermally treating the attached first and second substrate at a temperature of about 300° C. to about 700° C.

15. The method of claim 1, wherein the sacrificial layer pattern and the surface layer are planarized by a chemical mechanical polishing (CMP) process.
